(19) United States
(12) Patent Application Publication
(10) Pub. No.: US 2017/0198882 A1
(43) Pub. Date: Jul. 13, 2017

(54) LIGHT EMITTING DEVICE

(71) Applicant: Konica Minolta, Inc., Tokyo (JP)

(72) Inventors: Junya WAKAHARA, Yokohama-shi, Kanagawa-ken (JP); Naoki KIMURA, Takatsuki-shi, Osaka (JP)

(21) Appl. No.: 15/315,304

(22) PCT Filed: Jun. 29, 2015
(86) PCT No.: PCT/JP2015/068656

§ 371 Date: Nov. 30, 2016

(30) Foreign Application Priority Data
Sep. 26, 2014 (JP) 2014-196839

(51) Int. Cl. F21V 9/08; H01L 51/50; G02B 5/28; G02B 5/02; F21V 17/10; F21V 14/02

(52) U.S. Cl. CPC F21V 9/08; F21V 17/101; F21V 14/02; G02B 5/286; G02B 5/0257; G02B 5/0252; H01L 51/5012; F21Y 2115/20

(57) ABSTRACT

There is obtained a light emitting device including a configuration such that when a viewing angle is changed, a larger colour variation can be presented. The light emitting device comprises: an organic EL panel having a light emitting surface; a light diffusion layer provided on the light emitting surface; and a color difference creation layer provided on the light diffusion layer to receive lights from the light diffusion layer, change the lights in color and thus discharge them to allow a different color to be observed depending on a viewing angle.

### TECHNICAL FIELD

The present invention relates to a light emitting device including an organic EL panel.

### BACKGROUND ART

Japanese Laid-Open Patent Publication No. 2014-072204 (patent document 1) discloses an organic EL light emitting system which can obtain a decorative effect.

This light emitting system includes a plurality of types of organic EL light emitting panels different in viewing-angle dependence. Viewing-angle dependence is a nature allowing a contrast ratio and a visual performance when recognizing a color to be different depending on a viewing angle at which a light emitting surface is viewed.

Patent document 1 sets forth that, according to the thus configured light emitting system, visual performance to the user can be made different depending on a difference of a viewing angle, and accordingly, for example, a difference in visual performance at a viewing angle can be utilized to form a pattern etc. to allow a user to have such an impression that the pattern etc. is raised.

### CITATION LIST

### Patent Document

Patent document 1: Japanese Laid-Open Patent Publication No. 2014-072204

### SUMMARY OF INVENTION

### Technical Problem

There is a case in which it is preferable that a light emitting device including a configuration which can exhibit a visual effect allowing visual performance when recognizing a color to be different depending on a viewing angle be configured such that when the viewing angle is changed, a larger colour variation can be presented.

An object of the present invention is to provide a light emitting device including a configuration such that when a viewing angle is changed, a larger colour variation can be presented.

### Solution to Problem

A light emitting device according to one aspect of the present invention comprises an organic EL panel having a light emitting surface, a light diffusion layer provided on the light emitting surface, and a color difference creation layer provided on the light diffusion layer to receive lights from the light diffusion layer, change the lights in color and thus discharge them to allow a different color to be observed depending on a viewing angle.

### BRIEF DESCRIPTION OF DRAWINGS

FIG. 1 is a plan view showing a light emitting device in an embodiment.

FIG. 2 is a cross section taken along a line II-II shown in FIG. 1.

FIG. 3 is a cross section showing a state in which the light emitting device in the embodiment is disassembled.

FIG. 4 is a cross section, in an enlarged view, of a portion of an organic EL panel, light diffusion layer and color difference creation layer of the light emitting device in the embodiment.

FIG. 5 schematically shows a manner of using the light emitting device in the embodiment.

FIG. 6 illustrates variation in chromaticity in an example and comparative examples 1 and 2.

FIG. 7 represents a light distribution in a vertical plane in comparative example 1.

FIG. 8 represents a light distribution in a vertical plane in comparative example 1a.

FIG. 9 represents a light distribution in a vertical plane in an example.

FIG. 10 represents a light distribution in a vertical plane in comparative example 2.

FIG. 11 schematically shows a manner of using a light emitting device of the embodiment in an exemplary variation 1.

FIG. 12 schematically shows a manner of using a light emitting device of the embodiment in an exemplary variation 2.

### DESCRIPTION OF EMBODIMENTS

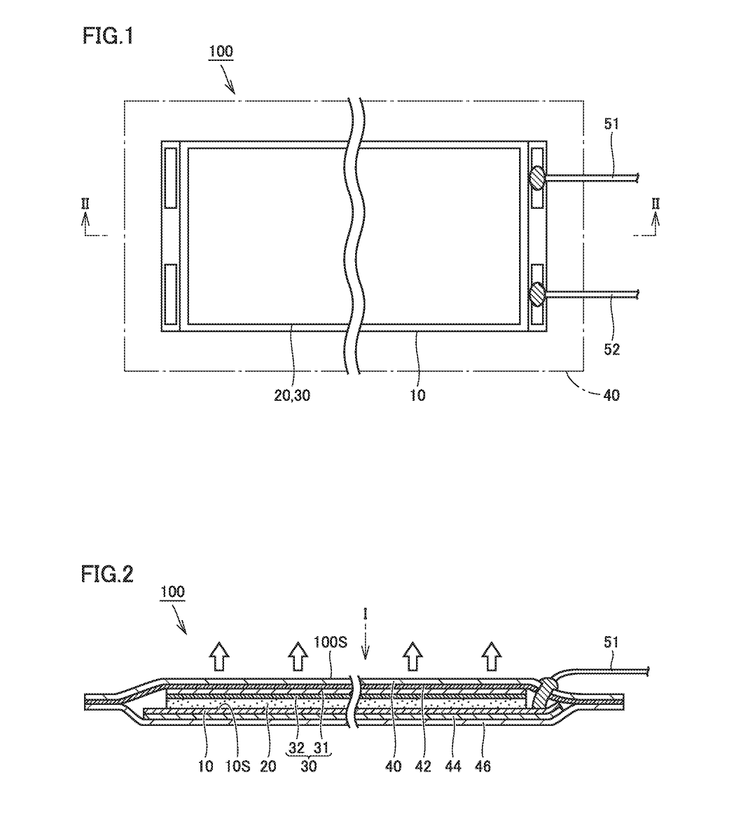

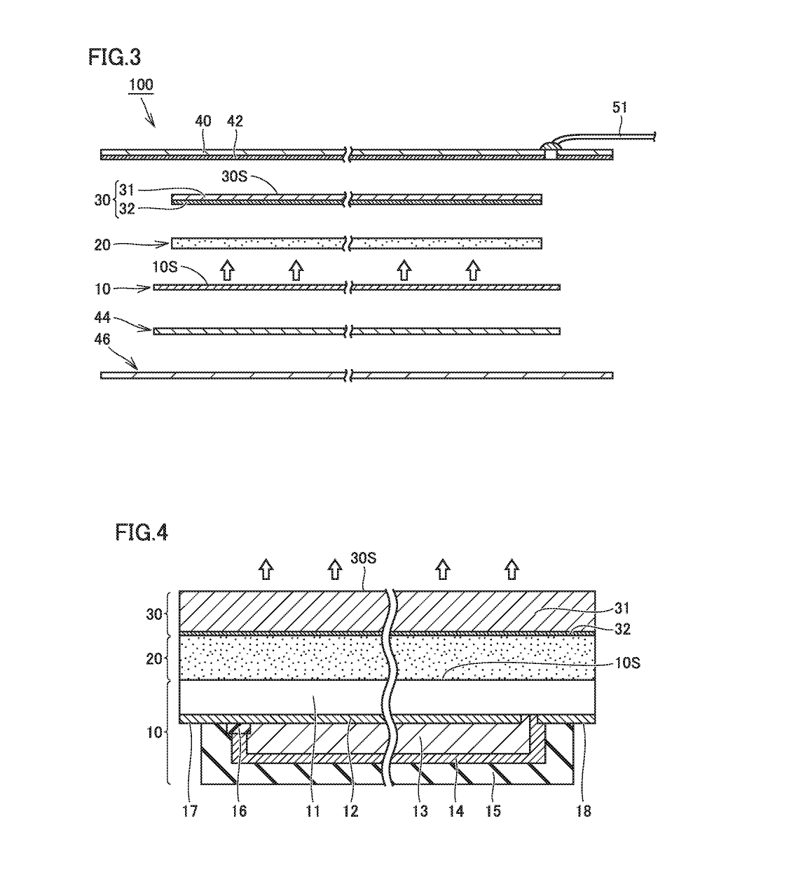

An embodiment will now be described hereinafter with reference to the drawings. Identical and corresponding components are identically denoted and may not be described repeatedly. FIG. 1 is a plan view showing a light emitting device 100, as seen in a direction indicated by an arrow I in FIG. 2. FIG. 2 is a cross section taken along a line II-II shown in FIG. 1. FIG. 3 is a cross section showing a state in which light emitting device 100 is disassembled.

With reference to FIG. 1 to FIG. 3, light emitting device 100 functions as a light emitting means to radiate light from a light emitting surface 100S (see FIG. 2). Light emitting device 100 can be used not only for lighting, decoration, and the like but also in various fields. Specifically, light emitting device 100 includes an organic EL panel 10, a light diffusion layer 20, a color difference creation layer 30, a front sheet 40, a pressure sensitive adhesive 42 (see FIG. 2, FIG. 3), a pressure sensitive adhesive tape 44 (see FIG. 2, FIG. 3), a back sheet 46 (see FIG. 2, FIG. 3), and lead wires 51 and 52 (see FIG. 1).

### (Organic EL Panel 10)

FIG. 4 is a cross section, in an enlarged view, of a portion of organic EL panel 10, light diffusion layer 20 and color difference creation layer 30. As shown in FIG. 4, organic EL panel 10 includes a transparent substrate 11, an anode 12, a light emitting layer 13, a cathode 14, a sealing member 15, and an insulating layer 16. Transparent substrate 11 is composed of glass, thin film glass, resin film etc. Transparent substrate 11 is a member which forms a light emitting surface 10S of organic EL panel 10 (also see FIG. 2 and FIG. 3).

Anode 12 is an electrically conductive film having transparency and is formed by depositing ITO etc. on transparent substrate 11. The ITO film is divided into two regions by patterning to form anode 12 and an electrode exit portion 17 (for the anode) and to form an electrode exit portion 18 (for the cathode). The ITO film of electrode exit portion 18 is connected to cathode 14.

Light emitting layer 13 generates light by receiving electric power. Light emitting layer 13 is configured by depositing a single layer or stacking a plurality of layers. Cathode 14 is for example aluminum (AL), and formed to cover light emitting layer 13. Insulating layer 16 is provided between cathode 14 and anode 12. Of cathode 14, a portion of a side opposite to a side at which insulating layer 16 is located is connected to electrode exit portion 18.

Sealing member 15 is formed of glass, thin film glass, resin film or the like. Sealing member 15 seals anode 12, light emitting layer 13, and cathode 14 entirely on transparent substrate 11. Electrode exit portions 17 and 18 are exposed from sealing member 15 for electrical connection. Electrode exit portions 17 and 18 are electrically connected to lead wires 51 and 52 (see FIG. 1), respectively, via an electrode pattern (an electrode land provided at two locations at ends of organic EL panel 10), an FPC (Flexible Printed Circuits), an electrically conductive adhesive etc.

Organic EL panel 10 emits light from light emitting surface 10S by receiving electric power from an external power supply (not shown) via lead wires 51 and 52 and electrode exit portions 17 and 18 (see a white arrow in FIG. 3). Transparent substrate 11 configuring organic EL panel 10 may be produced using a soft material (a material which has flexibility), such as resin film and thin film glass. This allows organic EL panel 10 to be entirely curved.

### (Light Diffusion Layer 20)

As shown in FIG. 2 to FIG. 4, light diffusion layer 20 is provided on light emitting surface 10S of organic EL panel 10. Light diffusion layer 20 has a function to diffuse light passing through light diffusion layer 20. When the light before passing through light diffusion layer 20 is compared with the light after having passed through light diffusion layer 20, the light after having passed through light diffusion layer 20 has a light distribution characteristic varied to have a small difference in quantity of light for each angle.

In other words, light diffusion layer 20 allows the light distribution characteristic of the light passing through light diffusion layer 20 to be close to Lambertian light distribution. The light distribution of the light after having passed through light diffusion layer 20 is closer to Lambertian light distribution than the light distribution of the light before passing through light diffusion layer 20. Light diffusion layer 20 having such a function is composed for example of OCF (Out Coupling Film).

Light diffusion layer 20 which has anisotropy may be used or light diffusion layer 20 which has isotropy may be used as long as it has an effect allowing the light distribution characteristic of the light passing through light diffusion layer 20 to be close to Lambertian light distribution. As light diffusion layer 20, one which includes fine particles in a matrix to utilize an internal scattering effect to diffuse light may be used, or one which has depression and projection (or a fine structure) on a surface of a matrix to utilize an interface reflection effect to diffuse light may be used.

A major portion of light generated inside organic EL panel 10 (at light emitting layer 13) is emitted from light emitting surface 10S (or extracted from light emitting surface 10S) and thereafter enters light diffusion layer 20. Light diffusion layer 20 provided on light emitting surface 10S can also exhibit a so-called light extraction effect that extracts a light component which is not emitted from light emitting surface 10S. By providing light diffusion layer 20 on light emitting surface 105, light extraction efficiency of organic EL panel 10 can be improved and hence light emission efficiency of light emitting device 100 can also be improved.

### (Color Difference Creation Layer 30)

As shown in FIG. 2 to FIG. 4, color difference creation layer 30 is provided on light diffusion layer 20. Light diffusion layer 20 is located between color difference creation layer 30 and organic EL panel 10. Color difference creation layer 30 of the present embodiment includes a rainbow film 31 and a pressure sensitive adhesive 32 provided to cover a surface of one side of rainbow film 31. Pressure sensitive adhesive 32 adheres rainbow film 31 and light diffusion layer 20 together. Pressure sensitive adhesive 32 is not an essential component and may be used as required.

Color difference creation layer 30 (rainbow film 31) receives lights from light diffusion layer 20, changes the lights in color and thus discharges them from a front surface 30S (see FIG. 3) to allow a different color to be observed depending on a viewing angle. Such a function that color difference creation layer 30 has can be implemented by the principle of structural color, for example. The above function of color difference creation layer 30 can be implemented, for example, by utilizing at least one effect of interference by a thin film, interference by a multilayer film, interference by diffraction, interference by a fine groove, interference by a fine projection, and scattering by a fine particle.

For color difference creation layer 30, instead of a so-called hologram sheet such as rainbow film 31, a dielectric multilayer film may be used. When using the dielectric multilayer film, how light interferes can be changed by a combination in thickness of each of a plurality of layers, a combination in quality of each of the plurality of layers, etc. In other words, the dielectric multilayer film can utilize an effect of interference by the multilayer film to change in color the lights received from light diffusion layer 20, and thus discharge them from front surface 30S (see FIG. 3) to allow a different color to be observed depending on a viewing angle.

### (Front Sheet 40 and Back Sheet 46, etc.)

As shown in FIG. 2 and FIG. 3, front sheet 40 and back sheet 46 are composed of a member which has a sealing function, such as PET film. Front sheet 40 and back sheet 46 each have an exterior size larger than organic EL panel 10 etc. (see FIG. 1). For the sake of convenience, in FIG. 1, front sheet 40 is shown transparently by using an alternate long and short dash line.

Front sheet 40 has one side having a surface provided with pressure sensitive adhesive 42 (see FIGS. 2 and 3). Pressure sensitive adhesive 42 adheres front sheet 40 and rainbow film 31 together. Pressure sensitive adhesive tape 44 is disposed between organic EL panel 10 and back sheet 46, and adheres organic EL panel 10 and back sheet 46 together. Front sheet 40 and back sheet 46 sandwich and thus seal organic EL panel 10, light diffusion layer 20, and color difference creation layer 30. By thus sealing and thus modularizing organic EL panel 10 etc., waterproofness can be obtained and organic EL panel 10 can also be protected against physical damage. An environment for use and a condition for use can be extended and application to various usages is possible.

The sealing is done in a procedure by way of example as follows: Initially, light diffusion layer 20 (OCF) and color difference creation layer 30 (pressure sensitive adhesive 32 and rainbow film 31) are stuck on light emitting surface 10S of organic EL panel 10 sequentially. Subsequently, pressure sensitive adhesive tape 44 is used to stick a back surface of organic EL panel 10 to back sheet 46. Subsequently, front sheet 40 is stuck to a side of front surface 30S (see FIG. 3) of color difference creation layer 30 via pressure sensitive adhesive 42. Thus, organic EL panel 10, light diffusion layer 20, and color difference creation layer 30 can be sealed.

When they are sealed, it is preferable to minimize air bubbles entering inside. For example, a device using a vacuum diaphragm which is described in Japanese Laid-Open Patent Publication Nos. 63-051092 or 02-160398 can be used. In the present embodiment, of front sheet 40, a portion corresponding to a location at which electric power is fed to organic EL panel 10 is provided with an opening. The electrode land provided at two locations at ends of organic EL panel 10 (see FIG. 1) is electrically connected to lead wires 51 and 52 (see FIG. 1) by utilizing this opening.

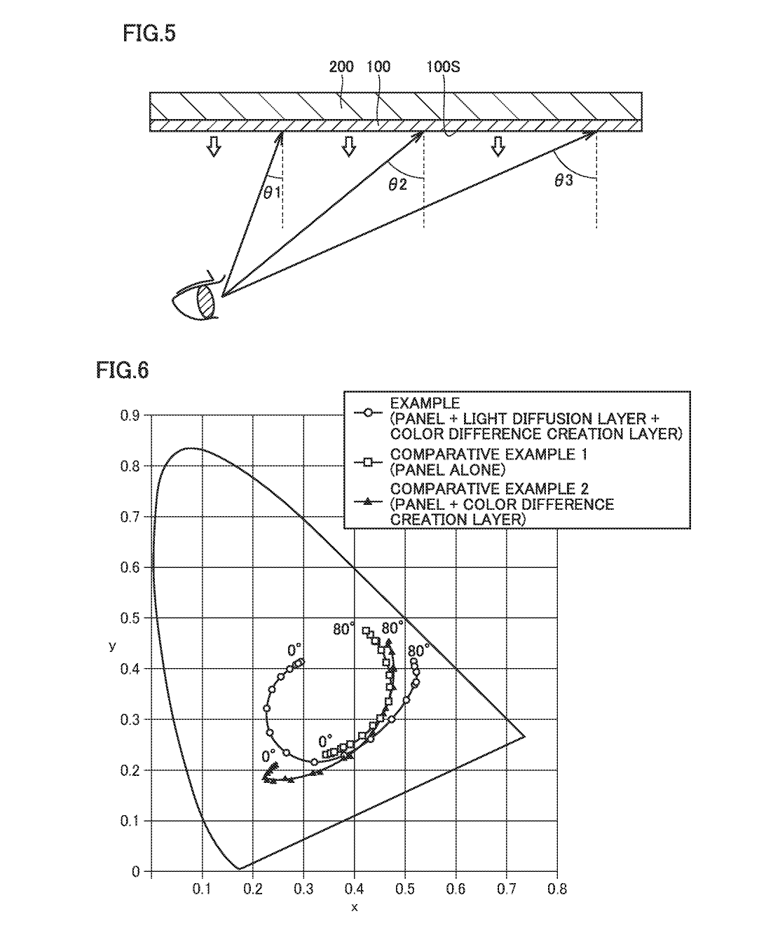

With reference to FIG. 5, light emitting device 100 that has the above configuration can be used with a holding substrate 200 for holding organic EL panel 10 etc (not shown in FIG. 5). Holding substrate 200 can also be regarded as one of the components of light emitting device 100. Holding substrate 200 may be a ceiling or a side wall surface. Holding substrate 200 is not limited to a fixed object such as a building and may be an external surface of a vehicle or the like.

Holding substrate 200 can be formed for example of PC (polycarbonate), ABS, PMMA or other similar plastic materials, SUS (stainless steel), aluminum, sheet steel or other similar metallic materials, or the like. As will be described later with reference to FIG. 11, holding substrate 200 may be shaped by injection molding, bending, press working, etc. to be a flat plate or a curved plate having a curvature. Light emitting device 100 can be stuck to holding substrate 200 with an adhesive, a pressure sensitive adhesive double-faced tape, etc.

### (Function and Effect)

Color difference creation layer 30 (see FIG. 2) that light emitting device 100 comprises receives lights from light diffusion layer 20 (see FIG. 2), changes the lights in color and thus discharges them to allow a different color to be observed depending on viewing angles 01, 02, 03. In the example shown in FIG. 5, θ1<θ2<θ3 is satisfied. In other words, the light radiated from light emitting surface 100S of light emitting device 100 can exhibit a visual effect such that visual performance when recognizing a color is different depending on a viewing angle.

Japanese Laid-Open Patent Publication No. 2014-072204 (patent document 1) referred to at the beginning, includes a plurality of types of organic EL light emitting panels different in viewing-angle dependence. In light emitting device 100 of the present embodiment, by using color difference creation layer 30, a visual effect can be exhibited such that visual performance when recognizing a color is different depending on a viewing angle.

As has been previously discussed, when light from organic EL panel 10 passes through light diffusion layer 20, a light distribution characteristic of the light is converted to be close to Lambertian light distribution. When the light before passing through light diffusion layer 20 is compared with the light after having passed through light diffusion layer 20, the light after having passed through light diffusion layer 20 has a light distribution characteristic varied to have a small difference in quantity of light for each angle. Color difference creation layer 30 receives lights from light diffusion layer 20, changes the lights in color and thus discharges them to allow a different color to be observed depending on a viewing angle.

A degree of variation of a color of light according to a viewing angle is larger in a case in which a diffusion effect of light diffusion layer 20 converts the light's light distribution characteristic to be close to Lambertian light distribution and subsequently the light is taken into color difference creation layer 30 than in a case in which light from organic EL panel 10 is directly taken into color difference creation layer 30. Thus according to light emitting device 100 of the present embodiment, when a viewing angle is changed, a larger colour variation can be presented. Furthermore, although an organic EL panel has a light distribution characteristic in various patterns, light diffusion layer 20 allows the light distribution characteristic to be converted to close to Lambertian light distribution, and whatever light distribution characteristic the organic EL panel may have, when a viewing angle is changed, a larger colour variation can be presented.

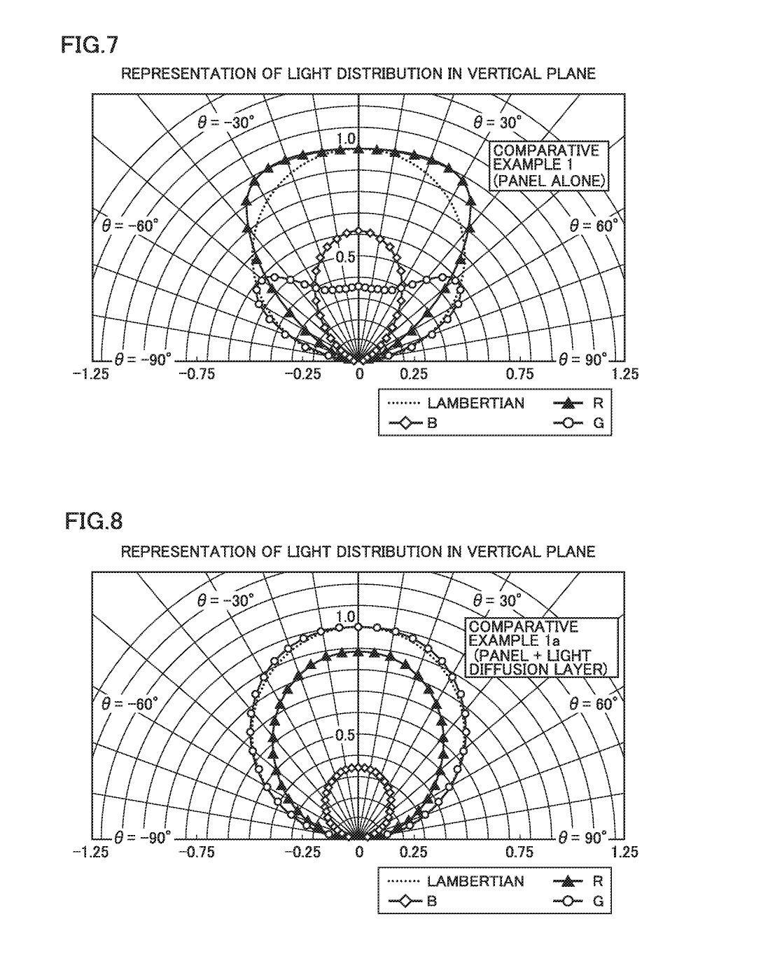

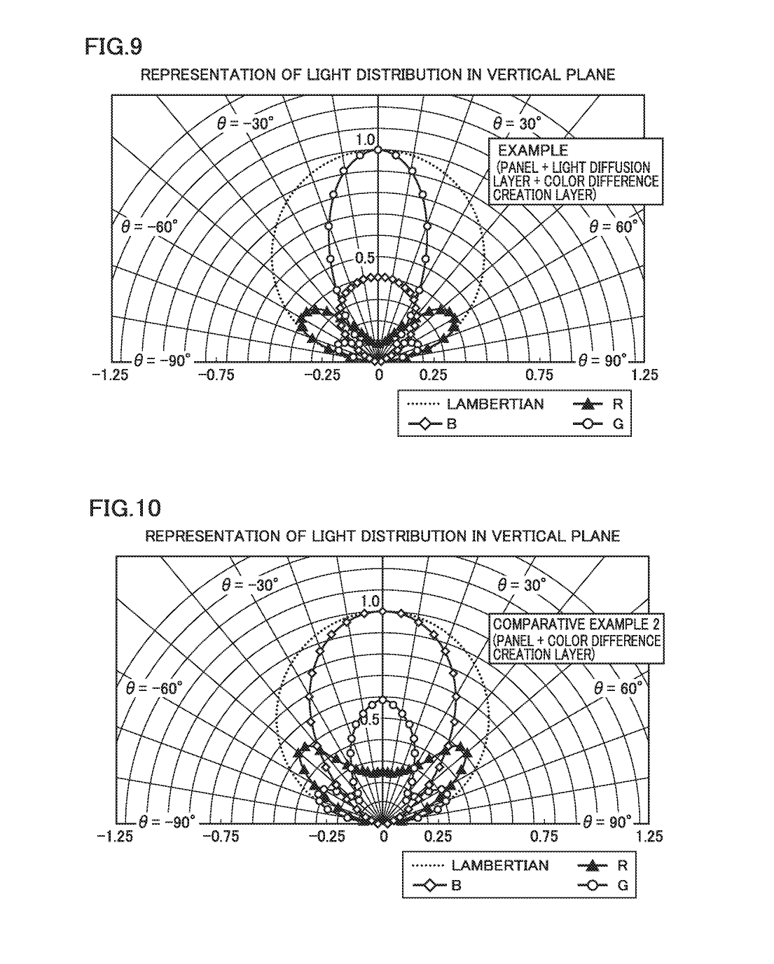

Hereinafter, FIG. 6 to FIG. 10 are used to provide a more specific description. An example described below (see FIG. 6, FIG. 9) has a configuration based on the above described embodiment. Comparative example 1 (see FIG. 6, FIG. 7) is not based on the above described embodiment and instead composed of organic EL panel 10 alone. Comparative example 1a (see FIG. 8) includes a configuration of comparative example 1 with light diffusion layer 20 alone added thereto. Comparative example 2 (see FIG. 6, FIG. 10) includes a configuration of comparative example 1 with color difference creation layer 30 alone added thereto.

FIG. 6 is a figure for illustrating variation in chromaticity in the example and comparative examples 1 and 2, as represented using an XYZ colorimetric system chromaticity diagram. FIG. 7 to FIG. 10 are figures representing light distributions within a vertical plane in comparative example 1, comparative example 1a, the example, and comparative example 2, respectively. In the figures showing light distributions, R represents a value of red color, G represents a value of green color, and B represents a value of blue color.

With reference to FIG. 6, in the case of comparative example 1 (panel alone), when a viewing angle is changed from 0 degree to 80 degrees, a color (a chromaticity) observed varies with a degree which is a range represented in FIG. 6 by a line indicated by squares. This range is smaller than any range of the example (indicated by circles) and comparative example 2 (indicated by triangles).

With reference to FIG. 7 and FIG. 8, when light diffusion layer 20 is added to comparative example 1 (panel alone) having such a light distribution as represented in FIG. 7, a light distribution as represented in FIG. 8 is obtained. In other words, in the configuration of comparative example 1a, a diffusion effect of light diffusion layer 20 allows a light distribution characteristic to be converted to be close to Lambertian light distribution. This is a phenomenon obtained in each color of R, G and B, and when light enters color difference creation layer 30, a state where a larger visual effect can be presented is formed.

With reference to FIG. 8 and FIG. 9, when color difference creation layer 30 is added to comparative example 1a (panel+light diffusion layer 20) having such a light distribution as represented in FIG. 8, a light distribution as represented in FIG. 9 is obtained. In other words, in the configuration of the example, light having a light distribution varied by light diffusion layer 20 to be close to Lambertian light distribution is radiated after having passed through color difference creation layer 30.

Passing through color difference creation layer 30 allows a visual effect to be obtained such that visual performance when recognizing a color is different depending on a viewing angle.

With reference to FIG. 6, in the case of the example, when a viewing angle is changed from 0 degree to 80 degrees, a color (a chromaticity) observed varies with a degree which is a range represented in FIG. 6 by a line indicated by circles. The line indicated by circles is longer than any of a line indicated by squares and a line indicated by triangles, and extends over a wide range. As compared with comparative example 1 (and comparative examples 1a and 2), the example has undergone the diffusion effect of light diffusion layer 20, and accordingly a characteristic which color difference creation layer 30 has can be sufficiently exhibited, and when a viewing angle is changed, a larger colour variation can be presented.

With reference to FIG. 10, on the other hand, when color difference creation layer 30 is directly added to comparative example 1 (panel alone) having such a light distribution as represented in FIG. 7 without light diffusion layer 20 interposed therebetween, a light distribution as represented in FIG. 10 is obtained. When a viewing angle is changed from 0 degree to 80 degrees, a color (a chromaticity) observed varies with a degree which is a range represented in FIG. 6 by a line indicated by triangles. This range is larger than comparative example 1 (marked with squares) and smaller than the example (marked with circles).

Thus light emitting device 100 of the present embodiment can dispense with an organic EL light emitting panel different in viewing-angle dependence, as in Japanese Laid-Open Patent Publication No. 2014-072204 (patent document 1) referred to at the beginning, since light emitting device 100 includes color difference creation layer 30 to be able to exhibit a visual effect such that visual performance when recognizing a color is different depending on a viewing angle. And through the diffusion effect of light diffusion layer 20, a characteristic which color difference creation layer 30 has can be sufficiently exhibited, and when a viewing angle is changed, a larger colour variation can be presented. Furthermore, by providing light diffusion layer 20 on light emitting surface 10S, light extraction efficiency of organic EL panel 10 can be improved and hence light emission efficiency of light emitting device 100 can also be improved.

### (First Exemplary Variation)

With reference to FIG. 11, light emitting device 100 in the embodiment can be used with another holding substrate 70 for holding organic EL panel 10 etc (not shown in FIG. 11). Holding substrate 70 is different from holding substrate 200 shown in FIG. 5, i.e., has a curved shape and can hold an organic EL panel in a curved state. FIG. 11 shows viewing angles such that θ4>θ5>θ6 is satisfied. Holding substrate 70, as well as holding substrate 200 (see FIG. 5) can also be regarded as one of the components of light emitting device 100. Holding substrate 70 may be a ceiling or a side wall surface. Holding substrate 70 is not limited to a fixed object such as a building and may be an external surface of a vehicle or the like.

Light emitting device 100 (or light emitting surface 100S) that is curved will be different from that in the form of a flat plate in how a viewing angle varies when a user standing at a prescribed position (or from a prescribed perspective) moves his/her line of sight from near to far away. Thus the form of the curved plate allows a visual effect different than the form of the flat plate to be obtained. By way of example, for the form of the flat plate, as a line of sight moves from near to far away, a viewing angle is gradually increased. In contrast, for the form of the curved plate, it is also possible to provide a configuration such that as a line of sight moves from near to far away, a viewing angle is gradually reduced.

### (Second Exemplary Variation)

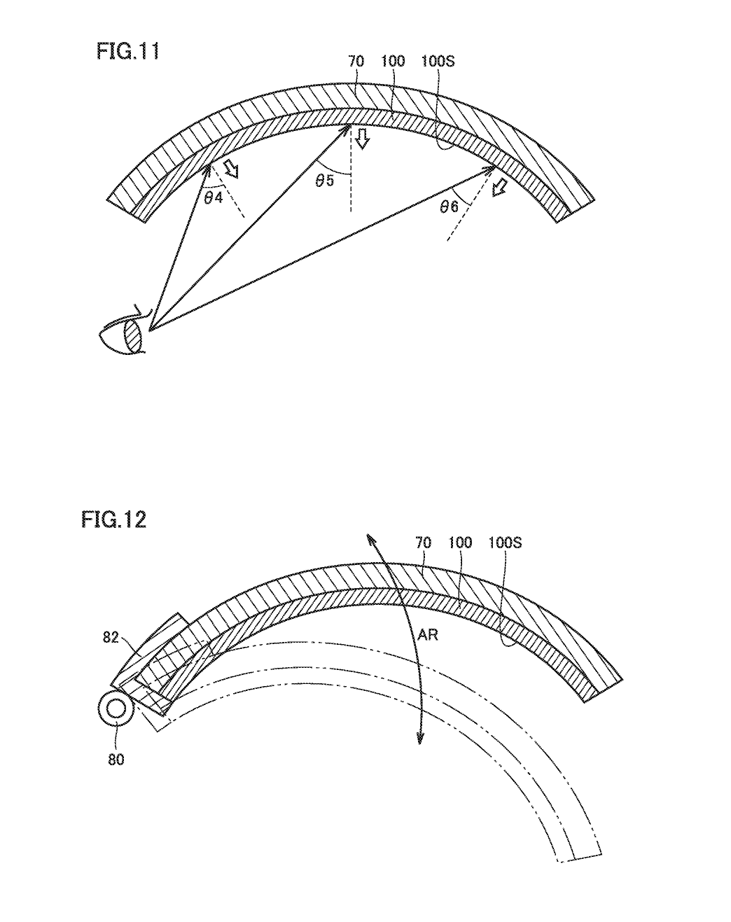

As shown in FIG. 12, at an end of light emitting device 100 and holding substrate 70, a pivotally supporting portion 80 may be provided via a bracket 82.

Pivotally supporting portion 80 supports an end of organic EL panel 10 via bracket 82 and holding substrate 70 pivotably about an axis (see an arrow AR). Pivotally supporting portion 80 may be driven by electrical machinery means such as a motor or may be driven by external force such as wind.

Light emitting device 100 (organic EL panel 10) supported pivotably about an axis allows light radiated from light emitting surface 100S of light emitting device 100 to be also rendered effectively. For example, even when a user who is stationary at a location faces in the same direction and does not move his/her line of sight, light emitting device 100 moves so that the user's viewing angle varies relative to light emitting surface 100S (or color difference creation layer 30). As the viewing angle varies, a visual effect to change a color is obtained.

The light emitting device described above includes an organic EL panel having a light emitting surface, a light diffusion layer provided on the light emitting surface, and a color difference creation layer provided on the light diffusion layer to receive lights from the light diffusion layer, change the lights in color and thus discharge them to allow a different color to be observed depending on a viewing angle.

Preferably, the color difference creation layer utilizes at least one effect of interference by a thin film, interference by a multilayer film, interference by diffraction, interference by a fine groove, interference by a fine projection, and scattering by a fine particle to change the light received from the light diffusion layer in color to allow a different color to be observed depending on a viewing angle.

Preferably, the color difference creation layer is formed of a hologram sheet or a dielectric multilayer film.

Preferably, a holding substrate is further comprised which has a curved shape for holding the organic EL panel in a curved state.

Preferably, a pivotally supporting portion is further comprised which supports an end of the organic EL panel pivotably about an axis.

According to the above configuration, when light from the organic EL panel passes through the light diffusion layer, the light has a light distribution characteristic converted to be close to Lambertian light distribution. The color difference creation layer receives lights from the light diffusion layer, changes the lights in color and thus discharges them to allow a different color to be observed depending on a viewing angle. A degree of variation of a color of light according to a viewing angle is larger in a case in which a diffusion effect of the light diffusion layer converts the light's light distribution characteristic to be close to Lambertian light distribution and subsequently the light is taken into the color difference creation layer than in a case in which light from the organic EL panel is directly taken into the color difference creation layer. Thus, according to the light emitting device, when a viewing angle is changed, a larger colour variation can be presented.

While an embodiment and an example have been described, it should be understood that the above disclosure is illustrative and non-restrictive in any respect. The scope of the present invention is defined by the terms of the claims, and is intended to include any modifications within the meaning and scope equivalent to the terms of the claims.

### REFERENCE SIGNS LIST

10: organic EL panel; 10S, 100S: light emitting surface; 11: transparent substrate; 12: anode; 13: light emitting layer; 14: cathode; 15: sealing member; 16: insulating layer; 17, 18: electrode exit portion; 20: light diffusion layer; 30: color difference creation layer; 30S: front surface; 31: rainbow film; 32, 42: pressure sensitive adhesive; 40: front sheet; 44: pressure sensitive adhesive tape; 46: back sheet; 51, 52: lead wire; 70, 200: holding substrate; 80: pivotally supporting portion; 82: bracket; 100: light emitting device.

1. A light emitting device comprising:
an organic EL panel having a light emitting surface;
a light diffusion layer provided on the light emitting surface; and
a color difference creation layer provided on the light diffusion layer to receive light from the light diffusion layer and change the light in color so that light discharged from the light emitting device is observed in a different color depending on a viewing angle.

2. The light emitting device according to claim 1, wherein the color difference creation layer utilizes at least one effect of interference by a thin film, interference by a multilayer film, interference by diffraction, interference by a fine groove, interference by a fine projection, and scattering by a fine particle to change the light received from the light diffusion layer in color so that light discharged from the light emitting device is observed in a different color depending on a viewing angle.

3. The light emitting device according to claim 1, wherein the color difference creation layer is formed of a hologram sheet or a dielectric multilayer film.

4. The light emitting device according to claim 1, further comprising a holding substrate having a curved shape and holding the organic EL panel in a curved state.

5. The light emitting device according to claim 1, further comprising a pivotally supporting portion supporting an end of the organic EL panel pivotably about an axis.

6. The light emitting device according to claim 4, configured such that by the holding substrate a viewing angle is gradually reduced as a line of sight moves from near to far away.

7. The light emitting device according to claim 5, wherein the pivotally supporting portion is driven by an electrical means to pivot the organic EL panel.
